(19) United States
(12) Patent Application Publication
(10) Pub. No.: US 2026/0002306 A1
(43) Pub. Date: Jan. 1, 2026

(54) LOAD ITEM DETECTION USING MOTOR DATA

(71) Applicant: WHIRLPOOL CORPORATION, Benton Harbor, MI (US)

(72) Inventors: Jesse Freitas Goncalves, Stevensville, MI (US); Ryan Bellinger, St. Joseph, MI (US); Victor Jafet Vargas, Stevensville, MI (US)

(21) Appl. No.: 18/757,877

(22) Filed: Jun. 28, 2024

(51) Int. Cl. D06F 34/18; D06F 34/04; D06F 34/20; D06F 34/28; D06F 58/38; D06F 58/46; D06F 58/50; D06F 103/06; D06F 103/24; D06F 103/32; D06F 103/34; D06F 103/36; D06F 103/54; D06F 105/46; D06F 105/52; D06F 105/56; D06F 105/58; G01R 21/06

(52) U.S. Cl. CPC D06F 34/18; D06F 34/04; D06F 34/20; D06F 34/28; D06F 58/38; D06F 58/46; D06F 58/50; G01R 21/06; D06F 2103/06; D06F 2103/24; D06F 2103/32; D06F 2103/34; D06F 2103/36; D06F 2103/54; D06F 2105/46; D06F 2105/52; D06F 2105/56; D06F 2105/58

(57) ABSTRACT

Hard-to-dry items are detected in a laundry load. Drum motor data is captured from a motor powering a rotating drum of a laundry appliance. Moving range (MR) and standard deviation (STD) are determined from the drum motor data. A hard-to-dry item model is used to predict presence or absence of heavy and/or hard-to-dry items in the laundry load, the hard-to-dry item model being determined using a nominal logistic regression of at least the MR and STD of the drum motor data in situations having presence or absence of heavy and/or hard-to-dry items. Cycle parameters for a cycle of operation of the laundry appliance are updated based on the prediction by the hard-to-dry item model of presence or absence of heavy and/or hard-to-dry items.

### TECHNICAL FIELD

Aspects of the disclosure generally relate to load size, type, and heavy and/or hard-to-dry item detection using motor torque, current, and/or speed information. Further aspects of the disclosure relate to detection and correction of airflow blockages based on the motor torque, current, and/or speed information.

### BACKGROUND

Settings for an operation cycle of a laundry treating appliance, such as a dryer, may depend on the size of a laundry load. In some laundry treating appliances, the user manually inputs a qualitative laundry load size (extra-small, small, medium, large, extra-large, etc.) through a user interface. However, it may be desirable to have the laundry appliance automatically determine the laundry load size because, for example, manual input may be perceived as inconvenient to the user and may result in inaccurate laundry load size determination due to the subjective nature of the estimation and/or due to the properties of the laundry items to be dried.

### SUMMARY

In one or more illustrative examples, a method for detecting hard-to-dry items in a laundry load includes capturing drum motor data from a motor powering a rotating drum of a laundry appliance; determining moving range (MR) and standard deviation (STD) of the drum motor data; using a hard-to-dry item model to predict presence or absence of heavy and/or hard-to-dry items in the laundry load, the hard-to-dry item model being determined using a nominal logistic regression of at least the MR and STD of the drum motor data in situations having presence or absence of heavy and/or hard-to-dry items; and updating cycle parameters for a cycle of operation of the laundry appliance based on the prediction by the hard-to-dry item model of presence or absence of heavy and/or hard-to-dry items.

In one or more illustrative examples, the drum motor data includes torque data indicative of torque being applied to the drum by the motor.

In one or more illustrative examples, the drum motor data includes speed data indicative of rotational speed of the drum being powered by the motor.

In one or more illustrative examples, the hard-to-dry item model utilizes additional parameters of data of the laundry appliance, including one or more of drum inlet temperature, drum outlet temperature, drum inlet relative humidity, drum outlet relative humidity, and/or conductivity sensing data from the laundry load.

In one or more illustrative examples, the drum motor data is captured periodically and applied to the hard-to-dry item model at least until the prediction of the hard-to-dry item model converges into an overall decision.

In one or more illustrative examples, the hard-to-dry item model is used throughout the cycle of operation to predict changes in the presence or absence of heavy and/or hard-to-dry items in the laundry load.

In one or more illustrative examples, the method further includes displaying an alert in a user interface of the laundry appliance responsive to detection of presence of heavy and/or hard-to-dry items in the laundry load.

In one or more illustrative examples, the method further includes sending an alert from the laundry appliance to a mobile device responsive to detection of presence of heavy and/or hard-to-dry items in the laundry load.

In one or more illustrative examples, updating the cycle parameters includes increasing the length of the cycle of operation and/or increasing heat of the cycle of operation.

In one or more illustrative examples, the method further includes using the MR and STD of fan motor data to determine the presence of an airflow obstruction of one or more vents of the laundry appliance; responsive to detection of the airflow obstruction, quantifying the airflow obstruction to determine a current system airflow velocity; and responsive to the current system airflow velocity indicating that corrective action is required, performing one or more corrective actions to address the airflow obstruction.

In one or more illustrative examples, the one or more corrective actions include reversing, increasing, or decreasing the motor speed.

In one or more illustrative examples, the one or more corrective actions include raising an alert.

In one or more illustrative examples, a system is provided for detecting hard-to-dry items in a laundry load. The system includes a hard-to-dry item model determined using a nominal logistic regression of at least moving range (MR) and standard deviation (STD) of drum motor data in situations having presence or absence of heavy and/or hard-to-dry items; and one or more controllers. The one or more controllers are configured to capture drum motor data from a motor powering a rotating drum of a laundry appliance, determine current MR and STD of the drum motor data, use the hard-to-dry item model to predict the presence or absence of heavy and/or hard-to-dry items in the laundry load, and update cycle parameters for a cycle of operation of the laundry appliance based on the prediction by the hard-to-dry item model of presence or absence of heavy and/or hard-to-dry items.

In one or more illustrative examples, the drum motor data includes one or more of: torque data indicative of torque being applied to the drum by the motor; and/or
speed data indicative of rotational speed of the drum being powered by the motor.

In one or more illustrative examples, the hard-to-dry item model utilizes additional parameters of data of the laundry appliance, including one or more of drum inlet temperature, drum outlet temperature, drum inlet relative humidity, drum outlet relative humidity, and/or conductivity sensing data from the laundry load.

In one or more illustrative examples, the drum motor data is captured periodically and applied to the hard-to-dry item model at least until the prediction of the hard-to-dry item model converges into an overall decision; and/or the hard-to-dry item model is used throughout the cycle of operation to predict changes in the presence or absence of heavy and/or hard-to-dry items in the laundry load.

In one or more illustrative examples, the one or more controllers are further configured to one or more of: display an alert in a user interface of the laundry appliance responsive to detection of presence of heavy and/or hard-to-dry items in the laundry load; and/or send the alert from the laundry appliance to a mobile device responsive to detection of presence of heavy and/or hard-to-dry items in the laundry load.

In one or more illustrative examples, updating the cycle parameters includes increasing the length of the cycle of operation and/or increasing heat of the cycle of operation.

In one or more illustrative examples, the one or more controllers are further configured to: use the MR and STD of fan motor data to determine the presence of an airflow obstruction of one or more vents of the laundry appliance; responsive to detection of the airflow obstruction, quantify the airflow obstruction to determine a current system airflow velocity; and responsive to the current system airflow velocity indicating that corrective action is required, perform one or more corrective actions to address the airflow obstruction.

In one or more illustrative examples, the one or more corrective actions include reversing, increasing, or decreasing the motor.

In one or more illustrative examples, the one or more corrective actions include raising an alert.

In one or more illustrative examples, a non-transitory computer-readable medium includes instructions for detecting hard-to-dry items in a laundry load that, when executed by one or more controllers, cause the one or more controllers to perform operations including to: capture drum motor data from a motor powering a rotating drum of a laundry appliance; determine moving range (MR) and standard deviation (STD) of the drum motor data; use a hard-to-dry item model to predict presence or absence of heavy and/or hard-to-dry items in the laundry load, the hard-to-dry item model being determined using a nominal logistic regression of at least the MR and STD of the drum motor data in situations having presence or absence of heavy and/or hard-to-dry items; and update cycle parameters for a cycle of operation of the laundry appliance based on the prediction by the hard-to-dry item model of presence or absence of heavy and/or hard-to-dry items.

### BRIEF DESCRIPTION OF THE DRAWINGS

FIG. 1 is a perspective view of an exemplary laundry treating appliance in the form of a clothes dryer according to one embodiment;

FIG. 2 is a schematic view of the clothes dryer of FIG. 1 according to one embodiment;

FIG. 3 is a schematic view of a control system according to one embodiment for the clothes dryer of FIGS. 1 and 2;

FIG. 4 illustrates an example of motor torque values captured from a motor control unit of the motor;

FIG. 5 illustrates an example chart of individual measurements of a load having a hard-to-dry clothes item as well as the moving range (MR) of the individual measurements;

FIG. 6 illustrates an example chart of standard deviation (STD) of the averages of the measurement points;

FIG. 7 illustrates an example chart of summarized data for MR and STD for a plurality of operation cycles of the clothes dryer;

FIG. 8 illustrates an example operation of the over time executing the utilizing the equation to reach a decision on whether a hard-to-dry item is present;

FIG. 9 illustrates an example graph of blower torque under blocked and unblocked secondary conditions;

FIG. 10 illustrates an example of a blockage due to a light item being stuck on the outlet grille due to suction from the airflow;

FIG. 11 illustrates an example process for determining the hard-to-dry item model;

FIG. 12 illustrates an example process for utilizing the hard-to-dry item model to adjust a cycle of operation of the laundry treating appliance based on the presence or absence of heavy and/or hard-to-dry laundry items; and

FIG. 13 illustrates an example process for the detection and correction of airflow blockages based on the motor torque, current, and/or speed information.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

Motor torque (and/or motor current) may be used determine overall load weight. However, overall load weight may be insufficient to inform whether there are specific heavy and/or hard-to-dry items within the load. In an improved approach, a torque (or current) over time analysis may be used to determine the presence or absence of heavy and/or hard-to-dry items (for the same overall load weight), as well as overall load size and type. Using the improved approach, heavy and/or hard-to-dry items (e.g., jeans, towels, comforters, etc.) within a load are identified, enabling the laundry treating appliance to estimate proper cycle times and prevent wet clothes while minimizing energy and time usage. The analysis may include inputting average moving ranges (MR) and standard deviations (STD) over time into a probability model, where the model is used to infer presence of heavy and/or hard-to-dry items in the load. Further aspects of the disclosure are discussed in detail herein. It will be appreciated that a heavy item may or may not constitute a hard-to-dry item and that a hard-to-try dry item may or may not constitute a heavy item. As such, the disclosed invention is suited to determining heavy items, hard-to-dry items, and/or heavy and hard-to-dry items.

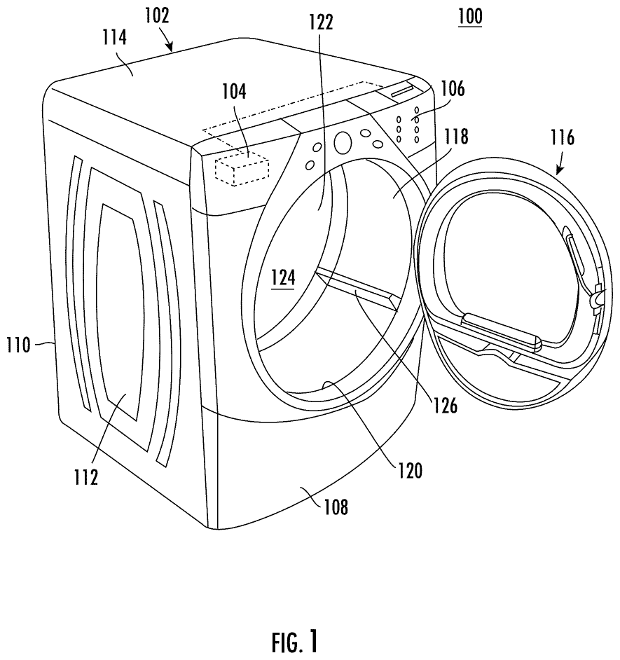

FIG. 1 illustrates one embodiment of a laundry treating appliance 100 in the form of a clothes dryer, according to aspects of the present disclosure. While the laundry treating appliance 100 is illustrated as a front-loading dryer, the laundry treating appliance 100 according to aspects of the present disclosure may be another appliance which performs a cycle of operation on laundry, non-limiting examples of which include a combination washing machine and dryer; a tumbling or stationary refreshing/revitalizing machine; an extractor; a non-aqueous washing apparatus; and a revitalizing machine.

As illustrated in FIG. 1, the laundry treating appliance 100 may include a cabinet 102 in which is provided a controller 104 that may receive input from a user through a user interface 106 for selecting a cycle of operation and controlling the operation of the laundry treating appliance 100 to implement the selected cycle of operation. The laundry treating appliance 100 may offer the user a number of pre-programmed cycles of operation to choose from, and each pre-programmed cycle of operation may have any number of adjustable cycle modifiers. Examples of such modifiers include, but are not limited to chemistry dispensing, load size, a load color, and/or a load type.

The cabinet 102 may be defined by a chassis or frame supporting a front wall 108, a rear wall 110, and a pair of side walls 112 supporting a top wall 114. A door 116 may be hingedly mounted to the front wall 108 and may be selectively moveable between opened and closed positions to close an opening in the front wall 108, which provides access to the interior of the cabinet 102.

A rotatable drum 118 may be disposed within the interior of the cabinet 102 between opposing front bulkhead 120 and rear bulkhead 122, which collectively define a treating chamber 124 having an open face that may be selectively closed by the door 116. The front bulkhead 120 and/or the rear bulkhead 122 may be formed of stamped aluminum or metal in some examples, or as a molded plastic component in other examples. The drum 118 may include at least one baffle or lifter 126. In some laundry treating appliances 100, there are multiple lifters 126 (e.g., three), but in other examples the lifters 126 may be omitted. If present, the lifters 126 may be located along the inner surface of the drum 118 defining an interior circumference of the drum 118. The lifters 126 may facilitate movement of laundry within the drum 118 as the drum 118 rotates.

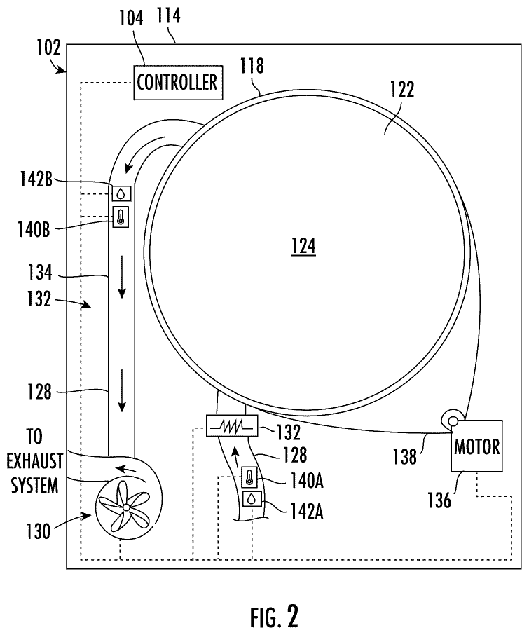

Referring to FIG. 2, an air flow system for the laundry treating appliance 100 is schematically illustrated and supplies air to the treating chamber 124 and then exhausts air from the treating chamber 124. The air flow system may have an air supply portion that may be formed in part by a supply air conduit 128, which has one end open to the ambient air and another end fluidly coupled to the treating chamber 124. For instance, the supply air conduit 128 may couple with the treating chamber 124 through an inlet formed in the rear bulkhead 122. A heater 132 may be provided within the supply air conduit 128 and may be operably coupled to and controlled by the controller 104. If the heater 132 is cycled on, the supplied air may be heated prior to entering the drum 118. The air supply system may further include an air exhaust portion that may be formed in part by an exhaust air conduit 134. A fan 130 may be provided within the exhaust air conduit 134. Operation of the fan 130 draws air into the treating chamber 124 by the supply air conduit 128 and exhausts air from the treating chamber 124 through the exhaust air conduit 134. The exhaust air conduit 134 may be fluidly coupled with a household exhaust duct (not shown) for exhausting the air from the treating chamber 124 to the outside environment. Other air flow systems are possible as well. For example, the fan 130 may be located in the supply air conduit 128 instead of in the exhaust air conduit 134 (not shown).

The laundry treating appliance 100 may also be provided with temperature sensors 140. The temperature sensors 140 may include an inlet temperature sensor 140A and an outlet temperature sensor 140B. One example of a temperature sensor 140 is a thermocouple. The temperature sensors 140 may be operably coupled to the controller 104 such that the controller 104 receives output from temperature sensors 140A, 140B. The laundry treating appliance 100 may also be provided with humidity sensors 142. Similarly, the humidity sensors 142 may include an inlet humidity sensors 142A and an outlet humidity sensor 142B. The humidity sensors 142 may be operably coupled to the controller 104 such that the controller 104 receives output from the humidity sensors 142.

The inlet temperature sensor 140A and the inlet humidity sensor 142A may be arranged inside or near the supply air conduit 128. The inlet temperature sensor 140A may be used to determine the temperature of the incoming air (before heating), while the inlet humidity sensor 142A may similarly be used to determine the humidity of the incoming air.

The outlet temperature sensor 140B and the outlet humidity sensor 142B may be mounted at any location downstream from the drum 118 and before the home exhaust connection, such as in or near the exhaust air conduit 134 of the laundry treating appliance 100. For example, the temperature sensor 140B and the outlet humidity sensor 142B may be located within or around the area of the exhaust air conduit 134. The temperature sensor 140B may sense the temperature of the exhaust air flow, while the outlet humidity sensor 142B may sense the humidity of the exhaust air flow.

The drum 118 may be rotated by a suitable drive mechanism, which is illustrated as a drum motor 136 and a coupled belt 138. The drum motor 136 may be operably coupled to the controller 104 to control the rotation of the drum 118 to complete a cycle of operation. Other drive mechanisms, such as direct drive, may also be used.

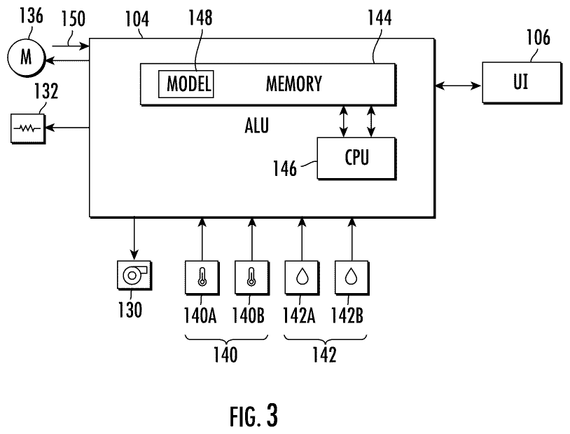

As illustrated in FIG. 3, the controller 104 may be provided with a memory 144 and a central processing unit (CPU) 146. The memory 144 may be used for storing the control software that may be executed by the CPU 146 in completing a cycle of operation using the laundry treating appliance 100 and any additional software. The memory 144 may also be used to store information, such as a database or table, and to store data received from the one or more components of the laundry treating appliance 100 that may be communicably coupled with the controller 104.

The controller 104 may be operably coupled with one or more components of the laundry treating appliance 100 for communicating with and/or controlling the operation of the component to complete a cycle of operation. For example, the controller 104 may be coupled with the fan 130 and the heater 132 for controlling the temperature and flow rate of the air flow through the treating chamber 124; the drum motor 136 for controlling the direction and speed of rotation of the drum 118; the temperature sensors 140A, 140B for receiving information about the temperature of the intake and exhaust air flows; the humidity sensors 142A, 142B for receiving information about the humidity of the intake and exhaust air flows; and the user interface 106 for receiving user selected inputs and communicating information to the user.

The controller 104 may also receive input from various other additional sensors, which are not shown for simplicity. Non-limiting examples of additional sensors that may be communicably coupled with the controller 104 include: an air flow rate sensor and a weight sensor.

Generally, in normal operation of the laundry treating appliance 100, a user first selects a cycle of operation via the user interface 106. The user may also select one or more cycle modifiers. In accordance with the user-selected cycle and cycle modifiers, the controller 104 may control the operation of the rotatable drum 118, the fan 130 and the heater 132, to implement the cycle of operation to dry the laundry. When instructed by the controller 104, the drum motor 136 rotates the drum 118 via the belt 138. The fan 130 draws air through the supply air conduit 128 and into the treating chamber 124, as illustrated by the flow vectors. The air may be heated by the heater 132. Air may be vented through the exhaust air conduit 134 to remove moisture from the treating chamber 124. During the cycle, treating chemistry may be dispensed into the treating chamber 124. Also during the cycle, output generated by the temperature sensors 140A, 140B and the humidity sensors 142A, 142B may be utilized to generate digital data corresponding to sensed operational conditions inside the treating chamber 124. The output may be sent to the controller 104 for use in calculating operational conditions inside the treating chamber 124, or the output may be indicative of the operational condition. Once the output is received, the controller 104 processes the output for storage in the memory 144. The controller 104 may convert the output during processing such that it may be properly stored in the memory 144 as digital data. The stored digital data may be processed in a buffer memory, and used, along with pre-selected coefficients, in algorithms to electronically calculate various operational conditions, such as a degree of wetness or moisture content of the laundry. The controller 104 may use both the cycle modifiers specified by the user and the additional information obtained by the sensors 140A-140B and 142A-142B to carry out the desired cycle of operation.

Dryer load size may be determined by the controller 104 using thermal signals such as those from the temperature sensors 140A, 140B. However, these signals can be noisy due to varying starting temperatures from back-to-back runs or different environmental conditions. Temperature variations may also occur based on the input voltage for electric models or gas properties for gas models (e.g., gas type, pressure, temperature, heating value). This can result in basic load size categories (small, medium, large) that are less accurate than desired.

The controller 104 may also perform dryer fabric type detection may rely on conductivity sensor data, sometimes supplemented with the temperature data. However, this approach may have limited capability beyond distinguishing synthetic loads from non-synthetic or mixed loads. Such an approach may be unable to detect one or a few hard-to-dry items (e.g., jeans) in an all-synthetic load.

Additionally, some approaches to load mass and type detection may require a long signal time before determining a result. As a result, a significant portion of the cycle may complete before detection occurs, which can hinder timely adaptations for cycle time, energy use, and fabric care. Moreover, customers may add or remove items during a cycle, but the long signal time may make it difficult to detect such changes during the cycle.

As discussed herein, the controller 104 may utilize a torque (or current) over time analysis to determine the presence or absence of heavy and/or hard-to-dry items (for the same overall load weight), as well as overall load size and type. Using this approach, heavy and/or hard-to-dry items (e.g., jeans) within the load are identified, enabling the laundry treating appliance 100 to estimate proper cycle times and prevent wet clothes while minimizing energy and time usage. The analysis may include inputting average MR and STD over time into a probability model 148, where the model 148 is used to infer presence of heavy and/or hard-to-dry items in the load.

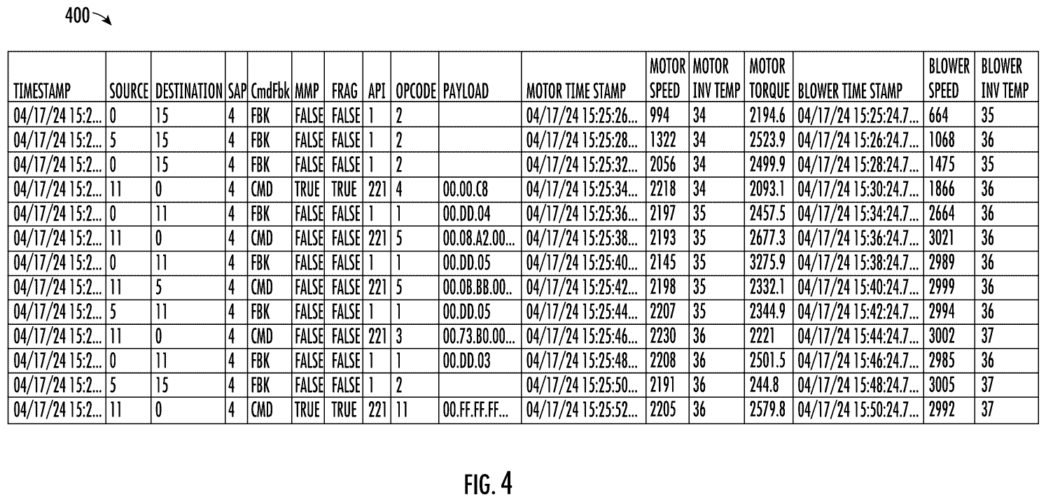

FIG. 4 illustrates an example of motor torque values 400 captured from the motor 136. The motor torque 150 of the motor 136 may be collected (e.g., via measuring the electrical power input, the voltage and the current in the power line driving the motor) and converted into its value in N-m. In an example, the motor 136 may incorporate a torque sensor configured to measure the torque and provide the value to the controller 104. In another example, the controller 104 may measure the torque indirectly by measuring the current draw of the motor 136. Using these values, an average of the MR of the motor torque 150 may be calculated. This average may be performed over a predefined quantity of measurement points.

The torque measurements may embody useful information about the load in the drum 118. If an opposite direction force is applied to the drum 118 while it is rotating, the motor torque 150 from the motor 136 will likely decrease.

During operation, the motor 136 applies a certain amount of torque to overcome the friction and drive the rotation of the drum 118 in that direction. This results in a positive torque reading since the motor 136 is working against the friction. When an opposite direction force to the drum 118 (e.g., due to the movement of items within the load), this is opposing the rotation that the motor 136 is trying to achieve. This force works against the motor torque 150. As a result of applying this opposite direction force, the torque required to maintain the counterclockwise rotation will change. The motor 136 will need to work differently to keep the drum 118 rotating in the intended direction because some of the force that previously hindered the rotation is now supplemented or countered by the applied force.

The application of an opposite direction force to the drum 118 while it's rotating will likely decrease the overall torque reading since the force opposes the effect of the motor 136 to drive rotation of the drum 118. Mathematically, the torque applied to the drum 118 by the motor 136 can be described using the formula:

$$τ = r \times F ,$$

where:
τ is the torque applied to the drum 118 (e.g., in Newton-meters, Nm),
r is the radius at which the force is applied (in meters, m),
F is the force applied (in Newtons, N).

In the case of the motor 136 driving the drum 118 counterclockwise, the torque applied by the motor 136 is positive because it is overcoming friction and other resistive forces. When an opposite direction force is applied to the drum 118, this effectively reduces the net torque applied to the drum 118. This applied force may be denoted as Fₒₚₚₒₛᵢₜₑ. If this force is also applied at a distance r from the center of rotation, the torque it produces would be:

$${τ}_{opposite} = r \times {F}_{opposite}$$

Since this force opposes the direction of rotation induced by the motor 136, it acts to decrease the net torque on the drum 118. So, the total torque applied to the drum 118, τₜₒₜₐₗ, considering both the torque from the motor 136 and the opposite force, may be represented as:

$${τ}_{total} = {τ}_{motor} - {τ}_{opposite} ,$$

where:
τₘₒₜₒᵣ is the torque applied by the motor.

If τₒₚₚₒₛᵢₜₑ is greater than τₘₒₜₒᵣ, then the total torque would become negative, indicating that the force being applying is strong enough to overcome the motor's torque and reverse the direction of rotation. If τₒₚₚₒₛᵢₜₑ is less than τₘₒₜₒᵣ, then the total torque would decrease, as the motor 136 is still exerting torque in the counterclockwise direction but the opposite force is reducing its effectiveness.

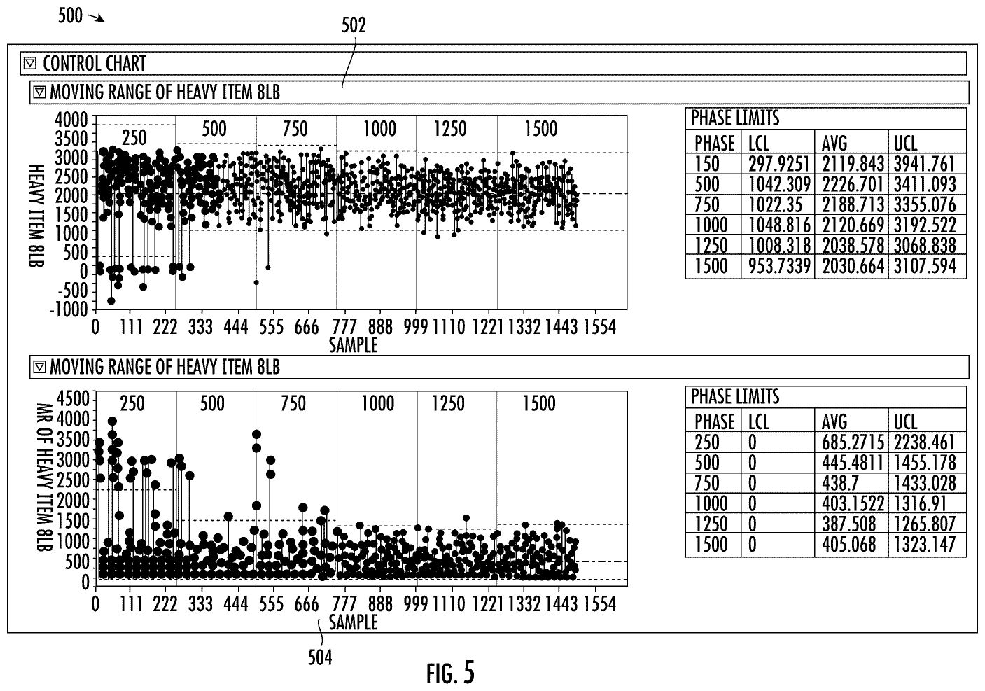

FIG. 5 illustrates an example chart of individual measurements 502 of a load having a hard-to-dry clothes item as well as the MR 504 of the individual measurements 502. These individual measurements 502 may be the captured motor torque 150 values as shown in FIG. 4. As can be seen in FIG. 5, the MR 504 average changes every 250 data points that are collected over time. This change in MR 504 is a result of the clothes losing humidity as they dry, and therefore getting lighter over time.

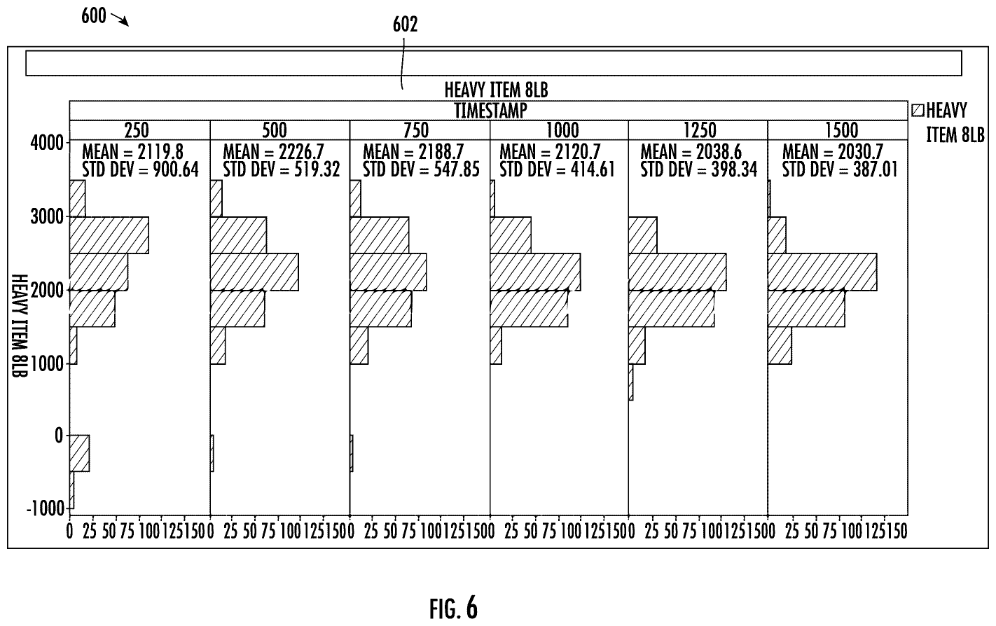

FIG. 6 illustrates an example chart 600 of STD 602 of the averages of the measurement points. As shown, the STD 602 average changes every 250 data points that are collected over time. This change in STD 602 is also a result of the clothes losing humidity as they dry, and therefore getting lighter over time. As can be seen, the standard deviation reduces over time, consistent with the reduction in the MR 504 over time.

A nominal logistic regression may be performed on the captured data. As discussed herein, nominal logistic regression, which may also be known as multinomial logistic regression, is a statistical analysis technique used for modeling relationships between categorical dependent variables with more than two levels (or categories) and one or more independent variables. As opposed to a binary logistic regression, which relates to dichotomous outcomes, nominal logistic regression may be used to handle outcomes with three or more unordered categories.

In the analysis, the outcome variable is categorical and can have more than two categories that are not ordered (i.e., nominal). The independent variables may be various data elements, which may be continuous and/or categorical. The structure of the model 148 estimates the probability of each category of the dependent variable relative to a reference category. A logistic function is used to ensure the predicted probabilities are between 0 and 1 and that the probabilities sum to 1 across all categories. The coefficients of the model 148 may be interpreted as the change in the log odds of being in a given category, compared to the reference category for a one-unit change in the predictor variable.

In an example, after treating the data and collecting the MRs 504 and STDs 602, a logistic regression may be fitted to allow the model 148 to indicate the probability, as a percentage, of the presence (or absence) of heavy and/or hard-to-dry items (such as heavy jeans) within the load. Specifically, the model 148 may indicate the statistical effect of the input factors (MR, STD, Time, etc.) and their interactions as a way to predict what is the probability of having heavy and/or hard-to-dry items within the load as a percentage. This analysis may be performed on data with and without the presence to hard-to-dry items, to provide ground truth for the fitting.

In an example, parameter estimates may be made for main effects, such as the effect of the moving range on the log odds of the dependent variable being in a particular category, the effect of time on the log odds of the dependent variable, and/or the effect of the standard deviation on the log odds of the dependent variable. Additionally, interactions between variables can also be included in the model 148 to determine whether an effect of one variable on the dependent variable depends on the level of another variable. Some possible interaction terms include MR*Time (the combined effect of moving range and time on the log odds), MR*STD (the combined effect of moving range and standard deviation on the log odds), Time*STD (the combined effect of time and standard deviation on the log odds), and MR*Time*STD (the three-way interaction effect of moving range, time, and standard deviation on the log odds).

An example probability equation of the model 148 may be defined in terms of one or more of: Intercept (e.g., the expected y value at zero x), MR, time, MR*time, STD, MR*STD, time*STD, MR*time*STD, etc. The example probability equation may be determined based on the logistic fit. For example, the example probability equation may be of the form:

$${L}_{in} [ no ] = {constant}_{1} + {constant}_{2} * MR + {constant}_{3} * time + ( MR - {constant}_{4} ) * ( time - {constant}_{5} ) * {constant}_{6} + {constant}_{7} * STD + ( MR - {constant}_{4} ) * ( STD - {constant}_{8} ) * {constant}_{9} + ( time - {constant}_{5} ) * ( STD - {constant}_{8} ) * {constant}_{10} + ( MR - {constant}_{4} ) * ( time - {constant}_{5} ) * ( STD - {constant}_{8} ) * {constant}_{11}$$

In an example, the fit may be performed using various software libraries. In one non-limited example, a nominal logistic regression model may be determined in R using the nnet package. In another example, the model may be determined in Python using the statsmodels package.

It should be noted that these are only example input factors, and the model 148 may be built using more, fewer, and/or different inputs and manipulations of the statistical model 148. While many examples herein relate to using motor torque 150, information about the load may also be contained in the speed data from the motor 136, since the speed control is continuously trying to adapt the motor current/torque to match the desired speed. Thus, a speed-based algorithm could also be used using speed as an input in addition to or instead of use of motor torque 150. While the speed and torque fluctuations may be correlated, they may also complement each other, so using inputs of both speed and torque may improve the capability of the model 148.

As some examples of additional variables and signals that could be added, the model 148 may be updated to utilize one or more of: inlet temperature of the drum 118 such as measured by temperature sensor 140A, outlet temperature of the drum 118 such as measured by temperature sensor 140B, inlet relative humidity of the drum 118 such as measured by the inlet humidity sensor 142A, outlet relative humidity of the drum 118 such as measured by the outlet humidity sensor 142B, and/or conductivity sensing data from the load such as measured by a conductivity sensor (not shown). In such examples, additional parameters may be estimated alone or in combination with the other factors. Such additional data elements may also serve as inputs to the model 148 and/or be used in a data fusion with the torque- and/or speed-based data. Inputs from other appliance algorithms of the laundry treating appliance 100 could also be used to enhance the performance of the model 148, such as information with respect to out-of-balance conditions, timing of introductions of treatment chemistries, activation or deactivation of heating elements, etc.

These additional parameters may be added to the combinations of parameters for which the parameter estimates are performed. In an example, if drum inlet temperature is added, then one or more of the following may be added to the logistic fit for determining the model 148: drum inlet temperature, drum inlet temperature*time, drum inlet temperature*STD, drum inlet temperature*STD*time, drum inlet temperature*MR, drum inlet temperature*MR*time, drum inlet temperature*MR*STD, drum inlet temperature*MR*STD*time, etc.

The model 148 may define a probability equation for determining the presence of heavy and/or hard-to-dry items in the laundry load. This example hard-to-dry item model 148 may be formed based on the result of the fitting of the parameters. The result of this fitting may be a set of constants for each of the parameters that may be used, in combination with the torque and other data inputs, to calculate the probability of having or not having a hard-to-dry items within the load.

For example, the estimation of whether an element is found may be determined by equations such as the following:

$$Prob [ no ] = 1 / ( 1 + Exp ( - {L}_{in} [ no ] ) ) ;$$

$$Prob ⌊ yes ⌋ = 1 / ( 1 + Exp ( {L}_{in} [ no ] ) )$$

Using those equations, the overall probability may be decided as the most likely choice as follows:

```
If Max(
    Prob[no] ⇒ “no”
    Prob[yes] ⇒ “yes”
      Else ⇒ “”
  )
```

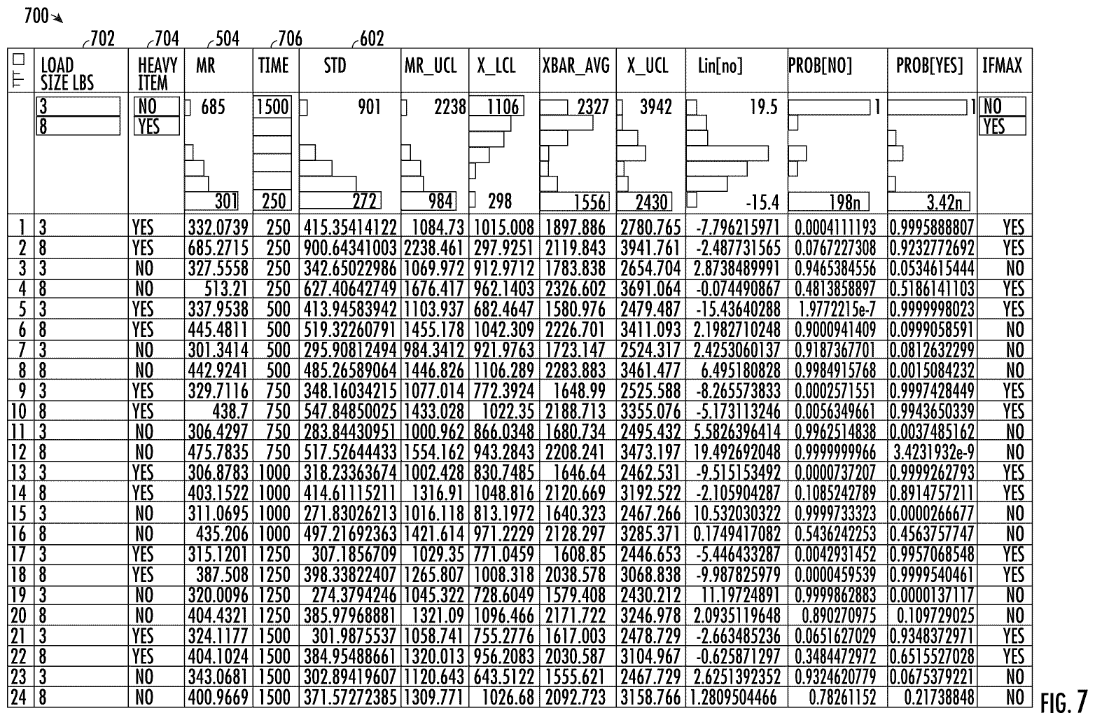

FIG. 7 illustrates an example chart of summarized data 700 for MR 504 and STD 602 for a plurality of operation cycles of the laundry treating appliance 100. The summarized data 700 also includes ground truth load weight 702 and ground truth heavy item presence 704. For each run, data points of motor torque 150 were captured over time, and the time 706 from cycle start of collection of the data is also shown. As shown, the Prob[no] and Prob[yes] values are provided for the summarized operation cycles, as well as the overall decision of IfMax.

During a cycle, as the clothes tumble inside the drum 118, the torque readings are applied through the model 148. This results in a probability of a heavy and/or hard-to-dry item being within the load.

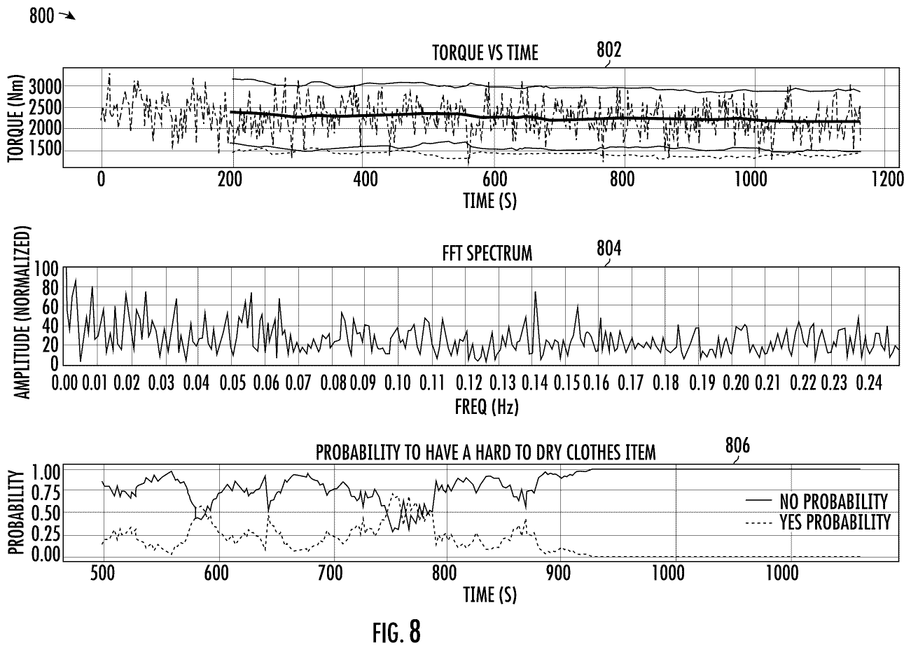

FIG. 8 illustrates an example operation of the laundry treating appliance 100 over time executing the utilizing the model 148 to reach a decision on whether a hard-to-dry item is present. In the top trace 802, torque measurements from the motor 136 are shown over time. In the middle trace 804, Fast Fourier Transform (FFT) spectrum of the normalized amplitude of the torque signal is shown. In the bottom trace 806, the Prob[no] and Prob[yes] values are shown over time, which eventually converge in an overall decision of no by IfMax.

By determining whether a hard-to-dry item is present, the laundry treating appliance 100 may adjust the cycle time or other cycle parameters. For example, if a hard-to-dry item is present, then the cycle time may be increased to ensure the full drying of all items in the load. In another example, the user interface 106 of the laundry treating appliance 100 may indicate to the user that the load includes a mixing of light and heavy and/or hard-to-dry items, which may make a drying cycle difficult. This feature may educate the user that drying time can varies based on the items within the load. The improved detection of the presence of heavy and/or hard-to-dry items may also reduce shrinkage over time by informing consumers that mixing items (as an example mixing heavy and light items) extends the mechanical action, which can damage their loads faster, thereby improving fabric care.

Moreover, as the determination of the presence of heavy and/or hard-to-dry items may be completed quicker than in other approaches, the cycle time may be adaptable. Thus, if the user adds or remove load items during the cycle (whether hard-to-dry or not), the laundry treating appliance 100 may detect the presence or absence of heavy and/or hard-to-dry items and may accordingly adjust the cycle time, during the cycle, and/or provide real-time feedback to the user of the change in the load and/or update in the cycle time.

Further, the disclosed approach combines data from one or more torque and speed signals using simple processing methods like the individual moving range (IMR) and standard deviation. The approach operates with subsampled torque and speed data at relatively low sampling rates (e.g., on the order of 0.5 Hz) through unsynchronized sampling, drum 118, and load frequencies over small time windows (e.g., 5 minutes). This results in lower bandwidth and potentially lower cost solutions, avoiding frequency domain analysis issues like aliasing and DTF leakage. The low sampling rates enable this approach to work with non-BPM motor technologies (e.g., induction motors) by adding a simple current transducer, as current and torque are proportional near the operating point of the motor 136. Moreover, since low sampling rates are sufficient, the disclosed approach does not require a high-speed processor and can be processed on a simple microcontroller. The torque and speed data may accordingly be communicated over a low-speed link (e.g., from a microcontroller unit (MCU) to an ACU). In other examples, higher sampling rates may be used to enhance performance, e.g., through improved detection speed and accuracy using various time and frequency domain techniques.

Thus, by identifying whether any heavy and/or hard-to-dry items are present, the disclosed approach may address issues with uneven drying and static at the end of the cycle and preventing over-drying. This ensures that the load reaches the proper dry level, whether or not the load contains heavy and/or hard-to-dry items.

As a further aspect, in addition to aiding in determining the presence or absence of heavy and/or hard-to-dry items, the motor torque 150 may be used to indicate the presence of an airflow blockage.

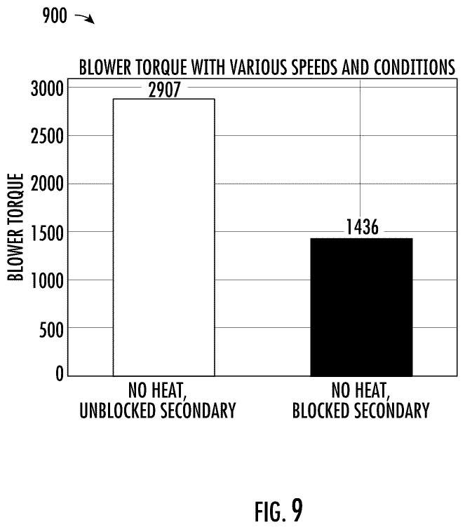

FIG. 9 illustrates an example graph 900 of blower torque from the fan 130 under blocked and unblocked secondary conditions. The left and right bars illustrate an example torque difference between a 0% and a 90% blocked secondary filter. Similar to the capture of the motor torque 150 of the drum motor 136, the fan torque of the fan 130 may be measured by the controller 104. As shown, the blower torque of the fan 130 drops significantly when there is an airflow blockage in the system.

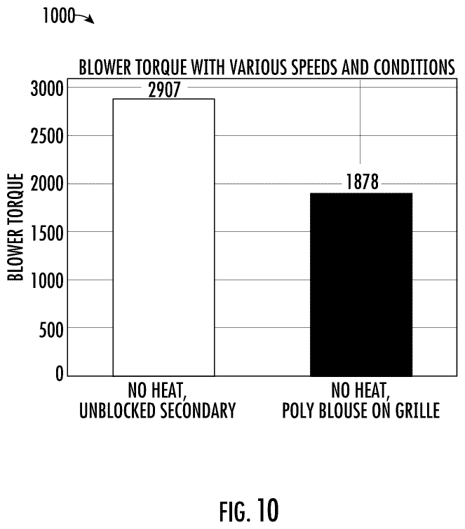

FIG. 10 illustrates an example graph 1000 of a blockage due to a light item (or items) being stuck on the outlet grille due to suction from the airflow. Here again, it can be seen that the blower torque of the fan 130 drops significantly when there is an airflow blockage.

Thus, similar to drum motor torque 150, the blower torque and/or speed may similarly be a useful measure for identifying primary and or secondary lint filter blockage. By measuring blower torque and/or speed over time, the laundry treating appliance 100 may predict the system airflow and the blockage percentage.

In an example, the laundry treating appliance 100 may perform a diagnostic before the cycle begins to check for blockages. If a blockage is detected, then the laundry treating appliance 100 may attempt to clear the blockages before initiating the cycle. In an example, by using the torque and/or speed of the fan 130, the laundry treating appliance 100 may identify if light items are stuck to the grill. If so, the laundry treating appliance 100 may adjust the speed of the blower (and/or the direction of the drum) to release the item and allow proper airflow through the cycle. In another example, the laundry treating appliance 100 may identify balling and tangling through the torque and speed of the drum 118, and may adjust the cycle by reversing, increasing, or decreasing the speed of the drum 118 to normalize the load. In yet another example, the user interface 106 of the laundry treating appliance 100 may be used to indicate the occurrence of blockages detected and/or to indicate the trade-offs related to cycle time or evenness of the drying of the load at the end of the cycle due to the blockage.

Moreover, by combining the torque/speed of the fan 130 and the torque/speed of the drum 118 with other signals available to the controller 104, such as moisture strip sensors and temperature sensors 140, and use of machine-learning models (e.g., neural networks and/or other artificial intelligence (AI)/machine learning (ML) models) the laundry treating appliance 100 may estimate cycle time, residual moisture content within the load, and cycle time.

The laundry treating appliance 100 can identify primary or secondary lint filter blockages by monitoring blower torque and speed. By combining blower and motor torque 150 and speed, the laundry treating appliance 100 can detect loads of similar weight but different volumes inside the drum 118 (e.g., 3 lbs of mixed load versus a comforter).

The laundry treating appliance 100 may adjust the temperature setting to properly dry the load size and type by recognizing the contents within the load. A variable speed drum 118 improves evaporation rates for different load sizes during the cycle.

By combining the torque and speed data from the blower and drum 118 with existing signals such as flow rate pressure, moisture strip sensors and temperature sensors 140 and using machine learning models 148 (neural networks and other AI/ML models 148), the machine can accurately estimate cycle time 706 and residual moisture content within the load.

The approach to detecting airflow issues may include the following operations. First, using a logistic regression approach (could be also other methods such as a k-nearest neighbor (KNN) or convolutional neural network (CNN) approach, etc.) the laundry treating appliance 100 determines whether there is a no blockage, a partial blockage, or a full blockage.

Additionally, using a linear regression or neural network (NN) approach, the laundry treating appliance 100 may estimate the current system airflow velocity. This may be estimated in meters per second or another logical unit of airflow. In some examples, the velocity flow may be converted into a volumetric flow rate (e.g., m\hat{ }3/s) given the geometry of the duct, and also to a mass airflow rate (e.g., kg/s) given the operating temperature of the dryer.

Using the blockage determination in combination with the airflow velocity determination, the laundry treating appliance 100 determines what percentage of system operation is compromised.

Through the user interface 106 of the laundry treating appliance 100 and/or an app of a mobile device in communication with the laundry treating appliance 100, the laundry treating appliance 100 may communicate to the user to indicate whether an action is required from the user or if the machine has made or can make attempts to cure the blockage.

By using torque and/or speed coming from the blower motor, the laundry treating appliance 100 can provide a fast determination of whether there is an airflow restriction. This is due to the fact that the torque and airflow restriction change quickly in relation to one another. Significantly, other factors such as starting mass and water temperature of the load or the dryer stored energy at the start of the cycle do not affect the determination, as the temperature dynamics are not needed for, as the blower torque and/or speed are quickly correlated with the airflow. Moreover, as discussed above, the detection of heavy and/or hard-to-dry items may be performed concurrent to the determination of airflow restrictions, using the same equipment and signals.

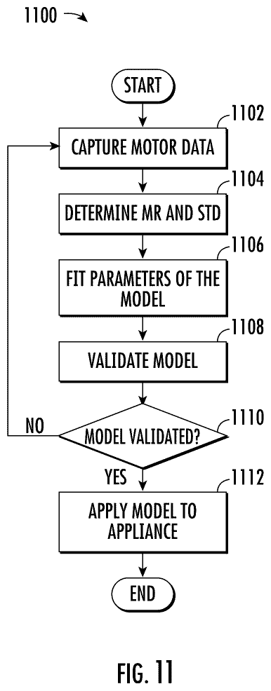

FIG. 11 illustrates an example process 1100 for determining the hard-to-dry item model 148. In an example, the process 1100 may be performed by one or more computing devices of the laundry treating appliance 100. In another example, the process 1100 may be performed by another computing device, such as at a factory or manufacturing center, and the hard-to-dry item model 148 once fitted may be stored to the controller 104 of the laundry treating appliance 100.

At operation 1102, data from motor 136 is captured for analysis. In many examples, this data may include torque data 152. However, as noted herein the data may additionally or alternatively include speed data. Additionally or alternatively, the data may also include one or more other parameters of data of the laundry appliance, including one or more of inlet temperature of the drum 118 such as measured by temperature sensor 140A, outlet temperature of the drum 118 such as measured by temperature sensor 140B, inlet relative humidity of the drum 118 such as measured by the inlet humidity sensor 142A, outlet relative humidity of the drum 118 such as measured by the outlet humidity sensor 142B, and/or conductivity sensing data from the load such as measured by a conductivity sensor (not shown). The data may be received by the controller 104 of the laundry treating appliance 100, such as from one or more sensors of the motor 136. In another example, the data may be provided from the laundry treating appliance 100 to a mobile device, hub device, another appliance, or another computing device for processing.

At operation 1104, the MR and STD for the torque data 152 or other data is determined. In an example, the MR and STD may be computed mathematically by the controller 104 or other computing device. In some examples, outlier data points may be excluded before performing the MR analysis. In one non-limiting example, data points that are more than two standard deviations from the STD may be excluded from the MR determination.

At operation 1106, the parameters of the model 148 are fitted. In an example, a logistic regression may be fitted to allow the model 148 to indicate the probability, as a percentage, of the presence (or absence) of heavy and/or hard-to-dry items (such as heavy jeans) within the load. Specifically, the model 148 may indicate the statistical effect of the input factors (MR, STD, Time, etc.) and their interactions as a way to predict what is the probability of having heavy and/or hard-to-dry items within the load as a percentage. This analysis may be performed on data with and without the presence to hard-to-dry items, to provide ground truth for the fitting. In an example, the fit may be performed using various software libraries, such as nnet or statsmodel.

At operation 1108, the model 148 is validated. In an example test data may be applied to the model 148 with known results for the presence or absence of heavy and/or hard-to-dry items. For instance a confusion matrix may be constructed based on the test data, and the model 148 may be analyzed to ensure that the predicted and actual results are correct for at least a minim percentage of the data.

At operation 1110, if the model 148 reaches the correct results based on the test data, then control proceeds to operation 1112 to apply to the laundry treating appliance 100. Otherwise, the process 1100 returns to operation 1102 to capture additional data. Or, in other examples, the process 1100 may terminate with an unsuccessful result.

At operation 1112, the model 148 is applied to the laundry treating appliance 100. In an example, the model 148 may be stored to the memory 144 of the controller 104 for use in analyzing cycles of operation of the laundry treating appliance 100. If the process 1100 is performed by one or more computing devices of the laundry treating appliance 100, then the model 148 may simply be set as active or transferred to a location for an active model for runtime use. However, if the process 1100 is performed by another computing device, such as at a factory or manufacturing center, then the model 148 may be transferred from the other computing device to the memory 144 of the laundry treating appliance 100. In some examples, the model 148 may be applied to the laundry treating appliance 100 at the factory during manufacture of the laundry treating appliance 100. In other examples, the model 148 may be applied to the laundry treating appliance 100 as a software update, either wirelessly, through a universal serial bus (USB) stick, etc. After operation 1112, the process 1100 ends.

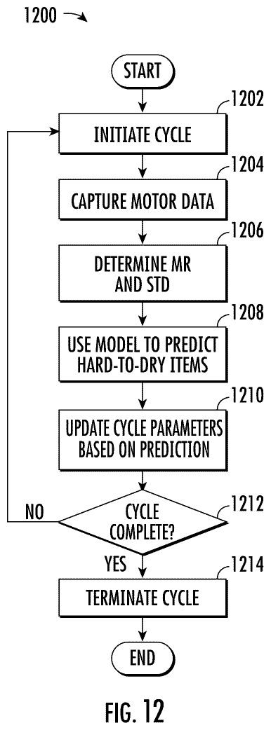

FIG. 12 illustrates an example process 1200 for utilizing the hard-to-dry item model 148 to adjust a cycle of operation of the laundry treating appliance 100 based on the presence or absence of heavy and/or hard-to-dry laundry items. In an example, the process 1200 may be performed by one or more computing devices of the laundry treating appliance 100, such as the controller 104. In another example, the process 1100 may be performed by another computing device, such as a mobile device, hub device, another appliance, or another computing device in communication with the laundry treating appliance 100.

At operation 1202, the cycle of the laundry treating appliance 100 is initiated. In an example, a controller 104 that may receive input from a user through a user interface 106 for selecting a cycle of operation and controlling the operation of the laundry treating appliance 100 to implement the selected cycle of operation. The laundry treating appliance 100 may offer the user a number of pre-programmed cycles of operation to choose from, and each pre-programmed cycle of operation may have any number of adjustable cycle modifiers. Examples of such modifiers include, but are not limited to chemistry dispensing, load size, a load color, and/or a load type.

At operation 1204, data from motor 136 is captured for analysis. This may be accomplished similar to as discussed with respect to operation 1104 of the process 1100.

At operation 1206, the MR and STD for the torque data 152 or other data is determined. This may be accomplished similar to as discussed with respect to operation 1106 of the process 1100.

At operation 1208, the model 148 is used to indicate the probability, as a percentage, of the presence (or absence) of heavy and/or hard-to-dry items (such as heavy jeans) within the load. In an example, the data collected at operation 1206 is applied to the model 148. The model 148 may have previously been trained and applied to the laundry treating appliance 100 as discussed above with respect to the process 1100. As shown in FIG. 8, the result of the operation of the model 148 over time may return an indication of whether hard-to-dry items are present.

At operation 1210, the cycle time and/or other cycle parameters of the laundry treating appliance 100 are updated based on the prediction. For example, if a heavy and/or hard-to-dry item is present, then the cycle time may be increased to ensure the full drying of all items in the load. In another example, the user interface 106 of the laundry treating appliance 100 may indicate to the user that the load includes a mixing light and heavy and/or hard-to-dry items, which may make a drying cycle difficult or require extended cycle time. This feature may educate the user that drying time can varies based on the items within the load. The improved detection of the presence of heavy and/or hard-to-dry items may also reduce shrinkage over time by informing users that mixing items (as an example mixing heavy and light items) extends the mechanical action, which can damage their loads faster, thereby facilitating improved fabric care behaviors by the user.

At operation 1212, the laundry treating appliance 100 determines whether the cycle is complete. For example, the laundry treating appliance 100 may determine if the time remaining for the cycle has reached zero. If so, the cycle is ended. If not, control returns to operation 1204 to continue to capture and analyze data. As the determination of the presence of heavy and/or hard-to-dry items may be completed quicker than in other approaches, the cycle time may therefore be analyzed and adapted throughout the cycle. Thus, if the user adds or remove load items during the cycle (whether hard-to-dry or not), the laundry treating appliance 100 may detect the presence or absence of heavy and/or hard-to-dry items and may accordingly adjust the cycle time, during the cycle, and/or provide real-time feedback to the user of the change in the load and/or update in the cycle time. After operation 1212 and the expiration of the cycle, the process 1200 is terminated at operation 1214 and the process 1200 ends.

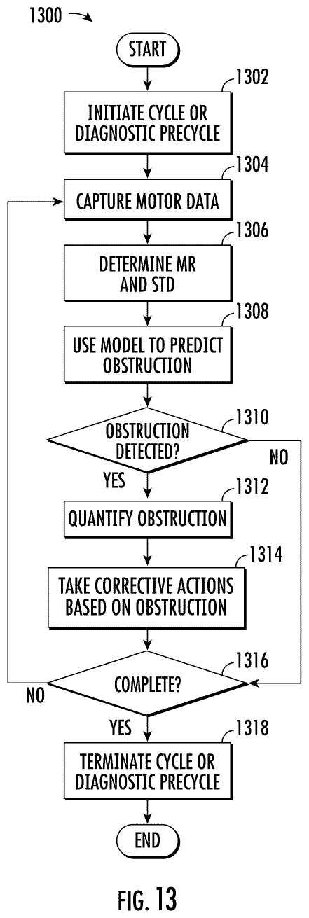

FIG. 13 illustrates an example process 1300 for the detection and correction of airflow blockages based on the motor torque 150, current, and/or speed information. In an example, the laundry treating appliance 100 may perform a diagnostic cycle before the laundry cycle according to the process 1300 before the cycle begins to check for blockages. If a blockage is detected, then the laundry treating appliance 100 may attempt to clear the blockages before initiating the laundry cycle. In another example, the process 1300 may be performed concurrent with, or otherwise in combination with the process 1200. In still other examples, the process 1300 may be performed separate from the operation of the process 1200 during the laundry cycle.

At operation 1302, the cycle or diagnostic precycle of the laundry treating appliance 100 is initiated. This may be accomplished similar to as discussed with respect to operation 1202 of the process 1200.

At operation 1304, data from the fan 130 is captured for analysis. This may be accomplished similar to as discussed with respect to operation 1104 of the process 1100 and operation 1204 of the process 1200, but for the fan 130 instead of the drum motor 136.

At operation 1306, the MR and STD for the fan speed, torque, and/or or other data is determined. This may be accomplished similar to as discussed with respect to operation 1106 of the process 1100 and operation 1206 of the process 1200.

At operation 1308, the model 148 is used to indicate the probability, as a percentage, of the presence (or absence) of an airflow obstruction. In an example, a logistic regression approach similar to as discussed above with respect to detection of heavy and/or hard-to-dry items may be used to determines whether there is a no blockage, a partial blockage, or a full blockage. In another example, a KNN supervised learning classifier may be used to analyze the data and uses proximity to make classifications or predictions about the received data. In yet another example, a CNN may be trained on the data and used in an inference mode based on the information captured at operation 1304 and processed at operation 1306 to infer whether or not an obstruction is present.

At operation 1310, if an obstruction is detected based on the determination at operation 1308, control proceeds to operation 1312. For example, if the probability determination at operation 1308 exceeds a predefined threshold indicative of a likely obstruction, then it is determined that an obstruction is detected. If the threshold is not reached, control proceeds to operation 1316 (discussed below).

At operation 1312, the obstruction is quantified. In an example, a linear regression or NN approach, the current system airflow velocity may be estimated. This estimate may be made in meters per second (MPS) or another logical unit for measuring dryer airflow.

At operation 1314, corrective actions are taken for the laundry treating appliance 100 based on the prediction and quantifying of the obstruction. In an example, if the current system airflow velocity indicates an obstruction of a size sufficient to attempt to correct, the laundry treating appliance 100 may adjust the speed of the blower to release the item and allow proper airflow through the cycle. In another example, the laundry treating appliance 100 may identify balling and tangling through the torque and speed of the drum 118, and may adjust the cycle by reversing, increasing, or decreasing the speed of the drum 118 to normalize the load. In yet another example, the user interface 106 of the laundry treating appliance 100 may be used to indicate the occurrence of blockages detected and/or to indicate the trade-offs related to cycle time or evenness of the drying of the load at the end of the cycle due to the blockage. In yet another example, the current system airflow velocity may be determined to be adequate, and only a warning or no action may be performed.

At operation 1316, similar to as discussed above with respect to operation 1212 of the process 1200, the laundry treating appliance 100 determines whether the cycle or diagnostic precycle is complete. If not, control returns to operation 1304. If the cycle is complete, the cycle or diagnostic precycle is terminated at operation 1316 and the process 1300 ends.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

For purposes of description herein the terms “upper,” “lower,” “right,” “left,” “rear,” “front,” “vertical,” “horizontal,” and derivatives thereof shall relate to the device as oriented in FIG. 1. However, it is to be understood that the device may assume various alternative orientations and step sequences, except where expressly specified to the contrary. It is also to be understood that the specific devices and processes illustrated in the attached drawings, and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module” or “system.” Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium include the following: an electrical connection having one or more wires, a portable computer diskette, a hard disk, a random access memory (RAM), a read-only memory (ROM), an erasable programmable read-only memory (EPROM) or Flash memory, an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

The flowcharts and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

What is claimed is:

1. A method for detecting hard-to-dry items in a laundry load, comprising:
capturing drum motor data from a motor powering a rotating drum of a laundry appliance;
determining moving range (MR) and standard deviation (STD) of the drum motor data;
using a hard-to-dry item model to predict presence or absence of heavy and/or hard-to-dry items in the laundry load, the hard-to-dry item model being determined using a nominal logistic regression of at least the MR and STD of the drum motor data in situations having presence or absence of heavy and/or hard-to-dry items; and
updating cycle parameters for a cycle of operation of the laundry appliance based on the prediction by the hard-to-dry item model of presence or absence of heavy and/or hard-to-dry items.

2. The method of claim 1, wherein the drum motor data includes torque data indicative of torque being applied to the drum by the motor.

3. The method of claim 1, wherein the drum motor data includes speed data indicative of rotational speed of the drum being powered by the motor.

4. The method of claim 1, wherein the hard-to-dry item model utilizes additional parameters of data of the laundry appliance, including one or more of drum inlet temperature, drum outlet temperature, drum inlet relative humidity, drum outlet relative humidity, and/or conductivity sensing data from the laundry load.

5. The method of claim 1, wherein the drum motor data is captured periodically and applied to the hard-to-dry item model at least until the prediction of the hard-to-dry item model converges into an overall decision.

6. The method of claim 1, wherein the hard-to-dry item model is used throughout the cycle of operation to predict changes in the presence or absence of heavy and/or hard-to-dry items in the laundry load.

7. The method of claim 1, further comprising displaying an alert in a user interface of the laundry appliance responsive to detection of presence of heavy and/or hard-to-dry items in the laundry load.

8. The method of claim 1, further comprising sending an alert from the laundry appliance to a mobile device responsive to detection of presence of heavy and/or hard-to-dry items in the laundry load.

9. The method of claim 1, wherein updating the cycle parameters includes increasing the length of the cycle of operation and/or increasing heat of the cycle of operation.

10. The method of claim 1, further comprising:
using the MR and STD of fan motor data to determine the presence of an airflow obstruction of one or more vents of the laundry appliance;
responsive to detection of the airflow obstruction, quantifying the airflow obstruction to determine a current system airflow velocity; and
responsive to the current system airflow velocity indicating that corrective action is required, performing one or more corrective actions to address the airflow obstruction.

11. The method of claim 10, wherein the one or more corrective actions include reversing, increasing, or decreasing speed of the motor.

12. The method of claim 10, wherein the one or more corrective actions include raising an alert.

13. A system for detecting hard-to-dry items in a laundry load, comprising:
a hard-to-dry item model determined using a nominal logistic regression of at least moving range (MR) and standard deviation (STD) of drum motor data in situations having presence or absence of heavy and/or hard-to-dry items; and
one or more controllers configured to:
capture drum motor data from a motor powering a rotating drum of a laundry appliance,
determine current MR and STD of the drum motor data,
based on the drum motor data, use the hard-to-dry item model to predict the presence or absence of heavy and/or hard-to-dry items in the laundry load, and
update cycle parameters for a cycle of operation of the laundry appliance based on the prediction by the hard-to-dry item model of presence or absence of heavy and/or hard-to-dry items.

14. The system of claim 13, wherein the drum motor data includes one or more of:
torque data indicative of torque being applied to the drum by the motor; and/or
speed data indicative of rotational speed of the drum being powered by the motor.

15. The system of claim 13, wherein the hard-to-dry item model utilizes additional parameters of data of the laundry appliance, including one or more of drum inlet temperature, drum outlet temperature, drum inlet relative humidity, drum outlet relative humidity, and/or conductivity sensing data from the laundry load.

16. The system of claim 13, wherein one or more of:
the drum motor data is captured periodically and applied to the hard-to-dry item model at least until the prediction of the hard-to-dry item model converges into an overall decision; and/or
the hard-to-dry item model is used throughout the cycle of operation to predict changes in the presence or absence of heavy and/or hard-to-dry items in the laundry load.

17. The system of claim 13, wherein the one or more controllers are further configured to one or more of:
display an alert in a user interface of the laundry appliance responsive to detection of presence of heavy and/or hard-to-dry items in the laundry load; and/or
send the alert from the laundry appliance to a mobile device responsive to detection of presence of heavy and/or hard-to-dry items in the laundry load.

18. The system of claim 13, wherein updating the cycle parameters includes increasing the length of the cycle of operation and/or increasing heat of the cycle of operation.

19. The system of claim 13, wherein the one or more controllers are further configured to:
use the MR and STD of fan motor data to determine the presence of an airflow obstruction of one or more vents of the laundry appliance;
responsive to detection of the airflow obstruction, quantify the airflow obstruction to determine a current system airflow velocity; and
responsive to the current system airflow velocity indicating that corrective action is required, perform one or more corrective actions to address the airflow obstruction.

20. The system of claim 19, wherein the one or more corrective actions include reversing, increasing, or decreasing speed of the motor.

21. The system of claim 19, wherein the one or more corrective actions include raising an alert.

22. A non-transitory computer-readable medium comprising instructions for detecting hard-to-dry items in a laundry load that, when executed by one or more controllers, cause the one or more controllers to perform operations including to:
capture drum motor data from a motor powering a rotating drum of a laundry appliance;
determine moving range (MR) and standard deviation (STD) of the drum motor data;
use a hard-to-dry item model to predict presence or absence of heavy and/or hard-to-dry items in the laundry load, the hard-to-dry item model being determined using a nominal logistic regression of at least the MR and STD of the drum motor data in situations having presence or absence of heavy and/or hard-to-dry items; and
update cycle parameters for a cycle of operation of the laundry appliance based on the prediction by the hard-to-dry item model of presence or absence of heavy and/or hard-to-dry items.
